(19) United States
(12) Patent Application Publication
(10) Pub. No.: US 2014/0169113 A1
(43) Pub. Date: Jun. 19, 2014

(54) Enhancing Memory Yield Through Memory Subsystem Repair

(71) Applicant: LSI Corporation, San Jose, CA (US)

(72) Inventors: Ting Zhou, Orinda, CA (US); Ross A. Kohler, Allentown, PA (US); Ruggero Castagnetti, Menlo Park, CA (US); Michael G. Yee, Cupertino, CA (US); Concetta Riccobene, Mountain View, CA (US)

(21) Appl. No.: 13/910,582

(22) Filed: Jun. 5, 2013

Related U.S. Application Data
(60) Provisional application No. 61/738,756, filed on Dec. 18, 2012.
(60) Provisional application No. 61/788,148, filed on Mar. 15, 2013.

(51) Int. Cl. G11C 29/00; G11C 29/04

(52) U.S. Cl. CPC G11C 29/70; G11C 29/04
USPC 365/200

(57) ABSTRACT

A memory system and a memory repair method for the memory system are disclosed. The method includes the steps of: organizing at least one repair block to serve as a shared repair resource for the plurality of memory blocks in the tiled memory; identifying a defective memory unit among the plurality of memory blocks in the tiled memory; identifying a replacement unit in the repair block for replacement of the defective memory unit; retrieving a set of memory blocks from the plurality of memory blocks in the tiled memory in response to a data access request, wherein the set of memory blocks retrieved containing the defective memory unit; retrieving the replacement unit from the repair block in response to the data access request; and replacing the defective memory unit in the set of memory blocks with the replacement unit.

### CROSS-REFERENCE TO RELATED APPLICATIONS

The present application claims the benefit under 35 U.S.C. §119(e) of U.S. Provisional Application Ser. No. 61/738,756, filed Dec. 18, 2012. Said U.S. Provisional Application Ser. No. 61/738,756 is hereby incorporated by reference in its entirety.

The present application also claims the benefit under 35 U.S.C. §119(e) of U.S. Provisional Application Ser. No. 61/788,148, filed Mar. 15, 2013. Said U.S. Provisional Application Ser. No. 61/788,148 is hereby incorporated by reference in its entirety.

### TECHNICAL FIELD

The present invention relates to the field of memory systems and particularly to memory system repairs.

### BACKGROUND

In computing, memory refers to the physical devices used to store programs or data on a temporary or permanent basis for use in a computer or other digital electronic device.

### SUMMARY

Accordingly, an embodiment of the present disclosure is directed to a memory system. The memory system includes a tiled memory having a plurality of memory blocks, a plurality of repair blocks serving as a shared repair resource for the plurality of memory blocks in the tiled memory, and a memory controller. The memory controller is configured for: identifying a defective memory block among the plurality of memory blocks in the tiled memory; identifying a replacement block among the plurality of repair blocks for replacement of the defective memory block; retrieving a set of memory blocks from the plurality of memory blocks in the tiled memory in response to a data access request, wherein the set of memory blocks retrieved containing the defective memory block; retrieving a set of repair blocks from the plurality of repair blocks in response to the data access request, wherein the set of repair blocks retrieved containing the replacement block for replacement of the defective memory block; and replacing the defective memory block in the set of memory blocks with the replacement block.

A further embodiment of the present disclosure is directed to a memory repair method for a tiled memory. The method includes the steps of: organizing a plurality of repair blocks to serve as a shared repair resource for the plurality of memory blocks in the tiled memory; identifying a defective memory block among the plurality of memory blocks in the tiled memory; identifying a replacement block among the plurality of repair blocks for replacement of the defective memory block; retrieving a set of memory blocks from the plurality of memory blocks in the tiled memory in response to a data access request, wherein the set of memory blocks retrieved containing the defective memory block; retrieving a set of repair blocks from the plurality of repair blocks in response to the data access request, wherein the set of repair blocks retrieved containing the replacement block for replacement of the defective memory block; and replacing the defective memory block in the set of memory blocks with the replacement block.

An additional embodiment of the present disclosure is also directed to a memory repair method for a tiled memory. The method includes the steps of: organizing at least one repair block to serve as a shared repair resource for the plurality of memory blocks in the tiled memory; identifying a defective memory unit among the plurality of memory blocks in the tiled memory; identifying a replacement unit in the repair block for replacement of the defective memory unit; retrieving a set of memory blocks from the plurality of memory blocks in the tiled memory in response to a data access request, wherein the set of memory blocks retrieved containing the defective memory unit; retrieving the replacement unit from the repair block in response to the data access request; and replacing the defective memory unit in the set of memory blocks with the replacement unit.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the present invention may be better understood by those skilled in the art by reference to the accompanying figures in which:

FIG. 1 is a block diagram illustrating operations of a tiled memory;

FIG. 2 is a block diagram illustrating operations of a tiled memory with repair blocks; and

FIG. 3 is a flow diagram illustrating a memory repair method.

### DETAILED DESCRIPTION

Reference will now be made in detail to the presently preferred embodiments of the invention, examples of which are illustrated in the accompanying drawings.

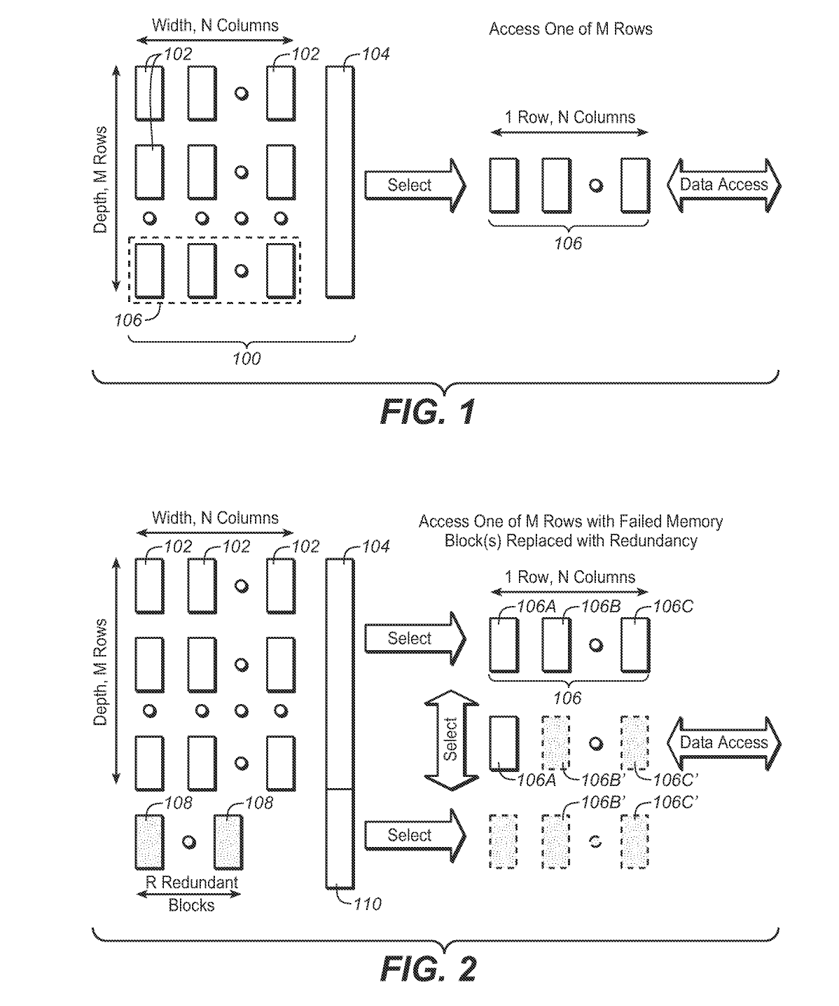

FIG. 1 is a block diagram illustrating operations of a tiled memory 100. As shown in FIG. 1, the tiled memory 100 includes a plurality of memory blocks 102 (may also be called macros) and an interface 104. Two types of tiling can be supported. For instance, tiling in depth direction can be used to construct a deeper memory than the physical memory is capable of. In FIG. 1, the memory is divided into M rows for illustrative purposes. Additionally and/or alternatively, tiling in width or word direction can be used to construct a wider memory than physical memory is capable of. In FIG. 1, the memory is divided into N columns for illustrative purposes.

It is noted that the tiled memory 100 is accessed in a per row fashion. When an input/output (I/O) device needs to access a particular row in the tiled memory, row 106 for instance, the interface 104 is utilized to select that particular row 106 and to establish communication between the selected row 106 and the I/O device to facilitate data access. It is contemplated that the interface 104 can be implemented utilizing a multiplexer as well as other suitable devices.

It is contemplated that some of the memory blocks 102 may fail during the operation. To provide repair capabilities for such tiled memories, in accordance with an embodiment of the present disclosure, one or more redundant memory blocks (macros) 108 are provided and shared as repair resource among the memory blocks 102 in the tiled memory. As illustrated in FIG. 2, by replacing failed memory blocks in the tiled memory with redundant memory blocks 108, the repairing mechanism is capable of repairing various types of memory defects, including peripheral circuits.

More specifically, in accordance with an embodiment of the present disclosure, the tiled memory 100 implements a memory self test logic to test each of the memory blocks being covered by the redundancy policy. When a failed memory block is detected, a repair controller/multiplexer 110 is informed and the failed memory block is identified. The repair controller 110 then diverts read/write access intended to the identified failed memory block to a redundancy block in the shared repair resource instead.

As illustrated in FIG. 2, when an I/O device needs to access a particular row in the tiled memory, row 106 for instance, the interface 104 is utilized to select that particular row 106 and provide data access. However, if blocks 106B and 106C in row 106 are identified as being defective, read/write access to these blocks must be redirected to their corresponding blocks in the redundant memory. To implement this block repair process, when a memory block fails, its identifier is passed along to the repair controller 110, which in turn can properly select a redundant memory block and establish the correspondence between them.

In the example depicted in FIG. 2, the identifiers for blocks 106B and 106C are provided to the repair controller 110. If the repair controller 110 receives the identifiers for blocks 106B and 106C for the first time, the repair controller 110 can allocate two redundant blocks 106B′ and 106C′ for 106B and 106C. When the repair controller 110 receives the identifiers for blocks 106B and 106C subsequently, the repair controller 110 can properly identify the corresponding redundant blocks 106B′ and 106C′ using the identifiers. It is contemplated that in one embodiment of the present disclosure, the memory blocks 102 and the redundant memory blocks 108 are indexed and the indices are used as identifiers. It is contemplated, however, that various other types of identifying information can be used as identifiers as long as they can properly identify the memory blocks.

In one embodiment, the redundant memory blocks are accessible in a per row fashion. In such a configuration, the repair controller 110 can utilize a multiplexer to select one or more rows that contain the replacement blocks 106B′ and 106C′ as illustrated in FIG. 2, and they will be provided together with 106A (e.g., using a multiplexer to select blocks 106A, 106B′ and 106C′) to the I/O device. In this manner, the original tiled memory structure is kept intact and repair is provided outside the tiling multiplexer 104. From a timing standpoint, there is only a 2:1 multiplexer added to the existing memory access paths.

An alternative multiplexer implementation when there is only one redundant block is to use a barrel shifter, similar to column repair within a memory, where each of the memory can be replaced by the repairing neighbor. The repairing neighbor is one and only one neighboring memory that can be used to replace the current memory. The repairing neighbor, when used as replacement, can be replaced by its own repairing neighbor. This repair action continues until the redundant memory is used.

In one embodiment, after a repair decision is made, the failed memory blocks in the tiled memory are put into sleep mode or disabled. The unused redundancy blocks can also be put into sleep mode or disabled. It is contemplated that memory access control signals can still be sent to the disabled memories and they will not cause any harm to the overall functionality. In addition, the redundant memory and memory been replaced are accessed at the same time in certain implementations to further improve timing. For instance, for the read data path, the tiling multiplexer 104 (i.e., the memory subsystem functional path) and the repair controller 110 (i.e., the repair path) can be configured to perform the selection processes in parallel. For write requests, write data and control signals are sent to the failed memory in the original tiled memory structure as well as the repair memory in the redundant memories. In this manner, the input signals to the original tiled memory structure can be left unmodified and there is no timing impact to the original tiled memory.

While replacing the failed memory blocks as described above provides adequate memory repair capabilities, it is contemplated that the replacement is not limited to the block/macro level repair. In one embodiment in accordance with the present disclosure, the memory self test logic is utilized to identify defects at a sub-block level. For instance, sub-blocks, bits, words, rows or columns among memories can be tested and defects can be identified. Identifier of such defective units (e.g., bits, words, rows, columns or the like) are then provided to the repair controller 110, and replacement units corresponding to the defective units can be retrieved and selectively merged with the non-defective units in the similar manner as described above. It is contemplated that smaller repairable unit sizes (e.g., identifying and repairing defects at bits or words level) generally require more processing/tracking compared to larger repairable unit sizes (e.g., identifying and repairing defects at rows or columns level). However, the specific repairable unit size defined for self testing and repairing is an implementation specific decision and may vary without departing from the spirit and scope of the present disclosure.

It is also contemplated that shared redundancy among the memory blocks as described above can be used in combination with dedicated redundancy within each block itself. Dedicated redundancy allows each memory block to provide repair capabilities for itself, and can co-exist with the shared redundancy scheme in repairing a group of memories. It is contemplated that the dedicated redundancy for each memory block can be implemented utilizing any self repair mechanisms or the like without departing from the spirit and scope of the present disclosure. In certain implementations, utilizing both types of redundancy may reduce repair multiplexer area and timing impact, and utilizing both types of redundancy may be utilized to server some other test purposes.

It is further contemplated that in one embodiment of the present disclosure, the group of memory blocks 102 as indicated in FIG. 2 forms a part of or an entire logical memory system/subsystem. That is, the memory blocks 102 function jointly to serve as at least a part of a memory system/subsystem. However, this is not required. For instance, individual memory blocks from different functional systems/subsystems can be grouped together for repair purposes without departing from the spirit and scope of the present disclosure. In this configuration, functionally the individual memory blocks belong to two or more different memory systems/subsystems, and they are joined together to form the memory element 100 as depicted in FIG. 2 only for repair purposes. Furthermore, the individual memory blocks can be identical memories or the same type of memories but with different configurations. The redundant memory block(s) can be configured to handle replacement for any failed memory without departing from the spirit and scope of the present disclosure.

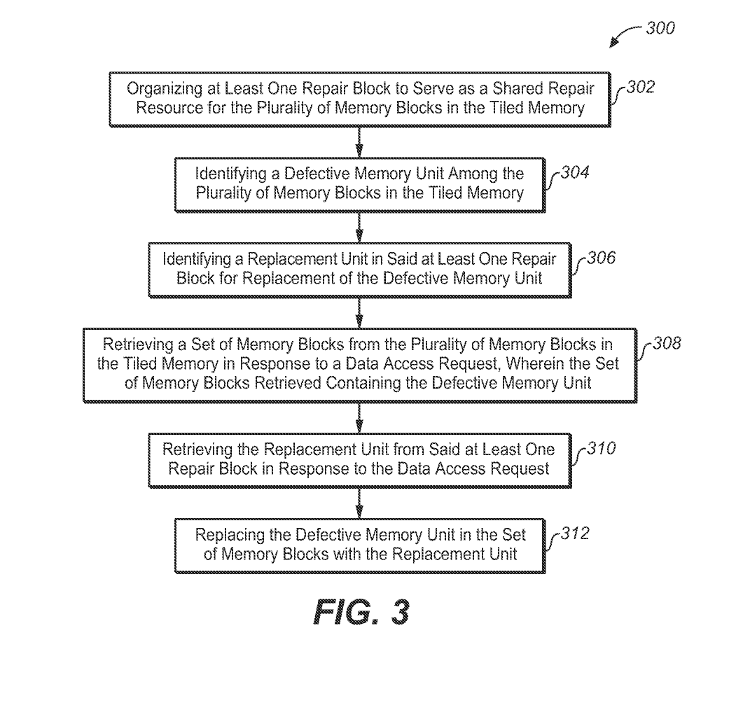

FIG. 3 is a flow diagram illustrating a memory repair method 300 for a tiled memory. In accordance with an embodiment of the present disclosure, one or more repair blocks are organized in step 302 to serve as a shared repair resource for the plurality of memory blocks in the tiled memory. If a defective memory unit in the tiled memory is identified in step 304, a replacement unit is also identified in step 306 for replacement of the defective memory unit. In this manner, upon receiving a data access request that accesses a set of memory blocks containing the defective memory unit in the tiled memory in step 308, the placement unit is also accessed in step 310 in response to the data access request. Step 312 then replaces the defective memory unit in the set of memory blocks retrieved from the tile memory with the replacement unit.

It is contemplated that the defective memory unit size and the replacement unit size need to be identical. However, this unit size is not required to be the same as the size of each memory block. Unit size smaller than the memory block size is utilized in certain embodiments in accordance with the present disclosure to provide sub-block level repair capabilities. It is also contemplated that more than one defective memory unit can be identified and replaced at once, and that step 308 and 310 can be performed in parallel to improve the performance. Furthermore, it is contemplated that the memory repair method is carried out by a memory controller in accordance with one embodiment of the present disclosure. For instance, the interface 104 and the repair controller 110 depicted in FIG. 2 are jointly referred to as the memory controller to carry out the memory repair method 300. Testing results indicate that the memory system and the memory repair method as described above greatly improves memory yield especially when memory nature yield is low.

It is also contemplated that the term “block” referenced above (e.g., repair blocks and memory blocks) is not limited to any particular type of memory hardware structure. A memory block, for example, can contain one or more groups and/or types of memory cells, arrays or devices. A memory block can also contain logical memory groups or the like. It is contemplated that the memory repair techniques described above are applicable to any data application that utilizes any of such blocks, wherein one or more defective blocks or sub-blocks can be replaced by accessing blocks or sub-blocks from the shared repair resource as previously described.

It is to be understood that the present disclosure may be conveniently implemented in forms of a software package. Such a software package may be a computer program product which employs a computer-readable storage medium including stored computer code which is used to program a computer to perform the disclosed function and process of the present invention. The computer-readable medium may include, but is not limited to, any type of conventional floppy disk, optical disk, CD-ROM, magnetic disk, hard disk drive, magneto-optical disk, ROM, RAM, EPROM, EEPROM, magnetic or optical card, or any other suitable media for storing electronic instructions.

It is understood that the specific order or hierarchy of steps in the foregoing disclosed methods are examples of exemplary approaches. Based upon design preferences, it is understood that the specific order or hierarchy of steps in the method can be rearranged while remaining within the scope of the present invention. The accompanying method claims present elements of the various steps in a sample order, and are not meant to be limited to the specific order or hierarchy presented.

It is believed that the present invention and many of its attendant advantages will be understood by the foregoing description. It is also believed that it will be apparent that various changes may be made in the form, construction and arrangement of the components thereof without departing from the scope and spirit of the invention or without sacrificing all of its material advantages. The form herein before described being merely an explanatory embodiment thereof, it is the intention of the following claims to encompass and include such changes.

What is claimed is:

1. A memory system, comprising:
a tiled memory, the tiled memory having a plurality of memory blocks;
a plurality of repair blocks, the plurality of repair blocks serving as a shared repair resource for the plurality of memory blocks in the tiled memory; and
a memory controller, the memory controller configured for:
identifying a defective memory block among the plurality of memory blocks in the tiled memory;
identifying a replacement block among the plurality of repair blocks for replacement of the defective memory block;
retrieving a set of memory blocks from the plurality of memory blocks in the tiled memory in response to a data access request, wherein the set of memory blocks retrieved containing the defective memory block;
retrieving a set of repair blocks from the plurality of repair blocks in response to the data access request, wherein the set of repair blocks retrieved containing the replacement block for replacement of the defective memory block; and
replacing the defective memory block in the set of memory blocks with the replacement block.

2. The memory system of claim 1, wherein the set of memory blocks retrieved from the tiled memory is a single row of memory blocks from the tiled memory.

3. The memory system of claim 1, wherein the set of memory blocks and the set of repair blocks are retrieved in parallel.

4. The memory system of claim 1, wherein the memory blocks in the tiled memory form at least a portion of a logical memory.

5. The memory system of claim 1, wherein the memory blocks in the tiled memory belong to a plurality of functionally distinct logical memories.

6. The memory system of claim 1, wherein the memory blocks in the tiled memory are identical in size and configuration.

7. The memory system of claim 1, wherein the memory blocks in the tiled memory are same type of memories with different configurations.

8. The memory system of claim 1, wherein each of the memory blocks in the tiled memory is further configured to include a dedicated memory repair mechanism.

9. A memory repair method for a tiled memory, the tiled memory having a plurality of memory blocks, the method comprising:
organizing a plurality of repair blocks to serve as a shared repair resource for the plurality of memory blocks in the tiled memory;
identifying a defective memory block among the plurality of memory blocks in the tiled memory;
identifying a replacement block among the plurality of repair blocks for replacement of the defective memory block;
retrieving a set of memory blocks from the plurality of memory blocks in the tiled memory in response to a data access request, wherein the set of memory blocks retrieved containing the defective memory block;
retrieving a set of repair blocks from the plurality of repair blocks in response to the data access request, wherein the set of repair blocks retrieved containing the replacement block for replacement of the defective memory block; and
replacing the defective memory block in the set of memory blocks with the replacement block.

10. The memory repair method of claim 9, wherein the set of memory blocks retrieved from the tiled memory is a single row of memory blocks from the tiled memory.

11. The memory repair method of claim 9, wherein the set of memory blocks and the set of repair blocks are retrieved in parallel.

12. The memory repair method of claim 9, wherein the memory blocks in the tiled memory form at least a portion of a logical memory.

13. The memory repair method of claim 9, wherein the memory blocks in the tiled memory belong to a plurality of functionally distinct logical memories.

14. The memory repair method of claim 9, wherein each of the memory blocks in the tiled memory is further configured to include a dedicated memory repair mechanism.

15. A memory repair method for a tiled memory, the tiled memory having a plurality of memory blocks, the method comprising:
organizing at least one repair block to serve as a shared repair resource for the plurality of memory blocks in the tiled memory;
identifying a defective memory unit among the plurality of memory blocks in the tiled memory;
identifying a replacement unit in said at least one repair block for replacement of the defective memory unit;
retrieving a set of memory blocks from the plurality of memory blocks in the tiled memory in response to a data access request, wherein the set of memory blocks retrieved containing the defective memory unit;
retrieving the replacement unit from said at least one repair block in response to the data access request; and
replacing the defective memory unit in the set of memory blocks with the replacement unit.

16. The memory repair method of claim 15, wherein the defective memory unit and the replacement unit are identical in unit size, and wherein the unit size is equal to a memory block size.

17. The memory repair method of claim 15, wherein the defective memory unit and the replacement unit are identical in unit size, and wherein the unit size is smaller than a memory block size.

18. The memory repair method of claim 15, wherein the set of memory blocks and the set of repair blocks are retrieved in parallel.

19. The memory repair method of claim 15, wherein the memory blocks in the tiled memory form at least a portion of a logical memory.

20. The memory repair method of claim 15, wherein the memory blocks in the tiled memory belong to a plurality of functionally distinct logical memories.
